(19) United States
(12) Patent Application Publication
(10) Pub. No.: US 2008/0187861 A1
(43) Pub. Date: Aug. 7, 2008

(54) Master Substrate and Method of Manufacturing a High-Density Relief Structure

(75) Inventor: Erwin Rinaldo Meinders, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/577,036

(22) PCT Filed: Oct. 12, 2005
(86) PCT No.: PCT/IB05/53349

§ 371 Date: Apr. 11, 2007

(30) Foreign Application Priority Data
Oct. 19, 2004 (EP) 04105148.3

(51) Int. Cl. G03F 7/004; G03F 1/14

(52) U.S. Cl. 430/270.11; 430/321

(57) ABSTRACT

The present invention relates to a master substrate (10) for optical recording comprising a recording layer (12) and a substrate layer (14), the recording layer comprises a growth dominated phase-change material, the chemical properties with respect to chemical agents of which may be altered due to a phase change induced by projecting light on the recording layer. For tracking purposes, the substrate layer comprises pre-grooves (16). The present invention further relates to a method of manufacturing a stamper for replicating a high-density relief structure.

### FIELD OF THE INVENTION

The present invention relates to a master substrate and to a method of manufacturing a high-density relief structure. Particularly, the present invention relates to providing a high-density relief structure using a conventional optical drive.

### BACKGROUND OF THE INVENTION

Relief structures that are manufactured on the basis of optical processes can, for example, be used as a stamper for the mass-replication of read-only memory (ROM) and pre-grooved write-once (R) and rewritable (RE) discs. The manufacturing of such a stamper, as used in a replication process, is known as mastering.

In conventional mastering, a thin photosensitive layer, spincoated on a glass substrate, is illuminated with a modulated focused laser beam. The modulation of the laser beam causes that some parts of the disc are being exposed by UV light while the intermediate areas in between the pits remain unexposed. While the disc rotates, and the focused laser beam is gradually pulled to the outer side of the disc, a spiral of alternating illuminated areas remains. In a second step, the exposed areas are being dissolved in a so-called development process to end up with physical holes inside the photo-resist layer. Alkaline liquids such as NaOH and KOH are used to dissolve the exposed areas. The structured surface is subsequently covered with a thin Ni layer. In a galvanic process, this sputter-deposited Ni layer is further grown to a thick manageable Ni substrate with the inverse pit structure. This Ni substrate with protruding bumps is separated from the substrate with unexposed areas and is called the stamper.

ROM discs contain a spiral of alternating pits and lands representing the encoded data. A reflection layer (metallic or other kind of material with different index of refraction coefficient) is added to facilitate the readout of the information. In most of the optical recording systems, the data track pitch has the same order of magnitude as the size of the optical readout/write spot to ensure optimum data capacity. Compare for example the data track pitch of 320 nm and the 1/e spot radius of 305 nm (1/e is the radius at which the optical intensity has reduced to 1/e of the maximum intensity) in case of Blue-ray Disc (BD). In contrary to write-once and rewritable optical master substrates, the pit width in a ROM disc is typically half of the pitch between adjacent data tracks. Such small pits are necessary for optimum readout. It is well known that ROM discs are read out via phase-modulation, i.e. the constructive and destructive interference of light rays. During readout of longer pits, destructive interference between light rays reflected from the pit bottom and reflected form the adjacent land plateau occurs, which leads to a lower reflection level.

Mastering of a pit structure with pits of approximately half the optical readout spot typically requires a laser with a lower wavelength than is used for readout. For CD/DVD mastering, the Laser Beam Recorder (LBR) typically operates at a wavelength of 413 nm and numerical aperture of the objective lens of NA=0.9. For BD mastering, a deep UV laser with 257 nm wavelength is used in combination with a high NA lens (0.9 for far-field and 1.25 for liquid immersion mastering). In other words, a next generation LBR is required to make a stamper for the current optical disc generation. An additional disadvantage of conventional photoresist mastering is the cumulative photon effect. The degradation of the photo-sensitive compound in the photoresist layer is proportional to the amount of illumination. The sides of the focused Airy spot also illuminates the adjacent traces during writing of pits in the central track. This multiple exposure leads to local broadening of the pits and therefore to an increased pit noise (jitter). Also for reduction of cross-illumination, an as small as possible focused laser spot is required. Another disadvantage of photoresist materials as used in conventional mastering is the length of the polymer chains present in the photoresist. Dissolution of the exposed areas leads to rather rough side edges due to the long polymer chains. In particular in case of pits (for ROM) and grooves (for pre-grooved substrates for write-once (R) and rewritable (RE) applications) this edge roughness may lead to deterioration of the readout signals of the pre-recorded ROM pits and recorded R/RE data. It is an object of the invention to provide a master substrate and a method of manufacturing a high-density relief structure on the basis of an optical writing process performed in a conventional optical drive.

### SUMMARY OF THE INVENTION

The above objects are solved by the features of the independent claims. Further developments and preferred embodiments of the invention are outlined in the dependent claims.

In accordance with the invention, there is provided a master substrate for optical recording comprising a recording layer and a substrate layer, the recording layer comprising a phase-change material, the properties with respect to chemical agents of which may be altered due to a phase change induced by projecting light on the recording layer, and the substrate layer comprising a structure for tracking purposes. Phase-change materials are applied in the well-known re-writable disc formats, such as DVD+RW and the recently introduced Blu-ray Disc (BD-RE). Phase-change materials can change from the as-deposited amorphous state to the crystalline state via laser heating. In many cases, the as-deposited amorphous state is made crystalline prior to recording of data. The initial crystalline state can be made amorphous by laser induced heating of the thin phase-change layer such that the layer melts. If the molten state is very rapidly cooled down, a solid amorphous state remains. The amorphous mark (area) can be made crystalline again by heating the amorphous mark to above the crystallisation temperature. These mechanisms are known from rewritable phase-change recording. The applicants have found that, depending on the heating conditions, a difference in etch velocity exists between the crystalline and amorphous phase. Etching is known as the dissolution process of a solid material in an alkaline liquid, acid liquid, or other type or solvent. The difference in etch velocity leads to a relief structure. Suitable etching liquids for the claimed material classes are alkaline liquids, such as NaOH, KOH and acids, such as HCl and HNO_{3.} The relief structure can, for example, be used to make a stamper for the mass replication of optical read-only ROM discs and possibly pre-grooved substrates for write-once and rewritable discs. The obtained relief structure can also be used for high-density printing of displays (micro-contact printing). The phase-change material for use as recording material is selected based on the optical and thermal properties of the material such that it is suitable for recording using the selected wavelength. In case the master substrate is initially in the amorphous state, crystalline marks are recorded during illumination. In case the recording layer is initially in the crystalline state, amorphous marks are recorded. During developing, one of the two states is dissolved in the alkaline or acid liquid to result in a relief structure. It is also possible that a difference in dissolution rate exists between the amorphous and crystalline state such that a relief structure remains after etching. Phase-change compositions can be classified into nucleation-dominated and growth-dominated materials. Nucleation-dominated phase-change materials have a relative high probability to form stable crystalline nuclei from which crystalline marks can be formed. On the contrary, the crystallisation speed is typically low. Examples of nucleation-dominated materials are Ge₁Sb₂Te₄ and Ge₂Sb₂Te₅ materials. Growth-dominated materials are characterized by a low nucleation probability and a high growth rate. Examples of growth-dominated phase-change compositions are compositions Sb₂Te doped with In and Ge and SnGeSb alloy. In case crystalline marks are written in an initial amorphous layer, typical marks remain that are conform the shape of the focused laser spot. The size of the crystalline mark can somewhat be tuned by controlling the applied laser power, but the written mark can hardly be made smaller than the optical spot. In case amorphous marks are written in a crystalline layer, the crystallisation properties of the phase-change material allow for a mark that is smaller than the optical spot size. In particular in case growth-dominated phase-change materials are used, re-crystallisation in the tail of the amorphous mark can be induced by application of proper laser levels at proper time scales relative to the time at which the amorphous mark is written. This re-crystallisation enables the writing of marks smaller than the optical spot size. The recording materials used in the present invention are preferably fast-growth phase-change materials, preferably of the composition: SnGeSb (Sn_{18.3}—Ge_{12.6}—Sb_{69.2}(At %)) or Sb₂Te doped with In Ge etc, such as InGeSbTe. The recording layer thickness is between 5 and 80 nm, preferably between 10 and 40 nm.

According to a preferred embodiment, a first interface layer is arranged between the recording layer and the substrate layer. The preferred material is ZnS—SiO2. The layer thickness is between 5 and 80 nm, preferably between 10 and 40 nm.

According to a further preferred embodiment, a second interface layer is arranged between the first interface layer and the substrate layer, and the first interface layer is etchable. While the first interface layer may be etchable, the second interface layer is not etchable and acts as a natural barrier. This layer is about 50 nm thick. In connection with the present embodiment, the patterned recording layer can be used as a mask layer for further illumination of the first interface layer. Thus, the relief structure can be made deeper thereby leading to a larger aspect ratio. The aspect ratio is defined as the ratio of the height and the width of the obstacles of the relief structure. The first interface layer is, for example, made of a photosensitive polymer. Illumination of the master substrate with for example UV light will cause exposure of the areas that are not covered with the mask layer. The areas of the interface layer covered with the mask layer are not exposed to the illumination since the mask layer is opaque for the used light. The exposed interface layer can be treated in a second development step, with a developing liquid not necessarily the same as the liquid used to pattern the mask layer. In this way, the relief structure present in the mask layer is transferred to the first interface layer such that a deeper relief structure is obtained.

According to another preferred embodiment of the invention, a heat-sink layer is arranged between the recording layer and the substrate layer. Preferably, a semi-transparent metallic layer serves as a heat-sink to remove the heat during recording. Semi-transparent metals, such as thin Ag, or transparent heat-sink layers, such as ITO or HfN, are proposed. The preferred layer thickness is between 5 and 40 nm.

Preferably, a leveling layer is arranged between the recording layer and the substrate layer. The leveling layer is added to level out the structure of the substrate such that a planar recording stack remains. The leveling layer is preferably deposited via a spincoat process, or another type of process that enables filling of the grooves. The material for the leveling layer is preferably a non-absorbing, spincoatable organic material. Another possibility is a pre-grooved substrate with a recording stack but without a leveling layer. In that case, the relief structure is superimposed on the pre-grooved structure. The developed master substrate with relief structure can be further processed to a metallic stamper with the inverse relief structure. This stamper is used for replication of discs/substrates. The readout of the replicated data pattern, which is superimposed on the groove structure, is not hampered by the groove structure.

According to a particularly preferable embodiment, a protection layer is arranged above the recording layer. The protection layer is made of a material that well dissolves in conventional developer liquids, such as KOH and NaOH. For example, the protection layer is made of ZnS—SiO₂ or photoresist. The layer thickness is between 5 and 100 nm, preferably between 10 and 25 nm.

According to a preferred embodiment of the present invention, the structure for tracking purposes comprises of a pre-groove structure. Preferably, a reflective layer is arranged on the pre-grooved structure in order to facilitate tracking. Thus, active tracking is possible, very similar to the tracking in a conventional optical drive. The grooves present in the disc generate an optical tracking error signal. The diffracted orders of the incident focused beam form overlapping and diverging cones. The resulting interference pattern is symmetric in case the beam is perfectly centered with respect to the groove. The difference signal, the so-called push-pull signal, is zero in this case. Deviation from the central position will lead to more or less light in one of the two detector parts. The difference signal becomes non-zero and can be used to re-align the spot with respect to the groove.

In accordance with the present invention, there is further provided a method of manufacturing a stamper for replicating a high-density relief structure comprising the steps of:

illuminating a master substrate in a conventional optical disc drive by a focused and modulated light beam, the master substrate comprising a recording layer and a substrate layer, the recording layer comprising a phase-change material, the properties with respect to chemical agents of which may be altered due to a phase change induced by projecting light on the recording layer, and the substrate layer comprising a structure for tracking purposes,

treating the previously illuminated master substrate with a solvent, thereby obtaining a relief structure

depositing a metallic layer on the relief structure,

growing the deposited layer to a desired thickness, and

separating the grown layer.

With respect to this method it is preferable that the step of growing the deposited layer to a desired thickness comprises electro-chemical plating.

The method according to the present invention is particularly advantageous on the basis of an embodiment, wherein the structure for tracking purposes comprises of a pre-groove structure, and an interference pattern projected from the pre-groove structure onto a detector is used for tracking. Thus, on the basis of the present invention optimum push-pull tracking will lead to an optical spot that perfectly follows the pre-groove. Optimum tracking is preferred in case a high-density master for mass-replication of optical discs is recorded. In that case, the relief structure should be a spiral of alternating lands and pits of different lengths, in which the data is encoded.

According to another preferred embodiment of the present invention, the structure for tracking purposes comprises of pre-grooves, and the light beam is deliberately placed off-track, so as to write a data pattern that is not restricted to following the pre-groove structure. If, for example, a two-dimensional high-density relief structure is desired that cannot be based on a spiral or circular data pattern, such as a two-dimensional optical card, a stamp for micro-contact printing or a raster, a more accurate positioning is required. This is achieved by the mentioned off-track placing of the light beam under consideration of the push-pull signal.

The proposed mastering substrate is particularly suitable for near-field mastering. Near field recording is based on an objective lens with a very high numerical aperture. This lens is preferably realized as a solid immersion lens (SIL), which is placed in close proximity of the data layer, distances between 20 and 100 nm are anticipated. Currently, systems with an NA of 1.6 and even 2.0 in combination with 405 nm wavelength laser light are considered as a possible system for next generation optical storage. If such a system is used in combination with conventional mastering substrates based on photoresist, contamination of the lens is likely to occur due to evaporation of all kind of photoresist constituents. However, the master substrates based on inorganic phase-change materials are very advantageous to use because of the avoidance of lens contamination. In such a near-field recording system, a pre-grooved master substrate can be used to master a high-density data pattern. From this relief pattern a stamper can be made that is used for the mass-replication of optical discs, both ROM discs (discs with pre-pits) and recordable and rewritable discs (discs with a pre-groove).

These and other aspects of the invention will be apparent from and elucidated with reference to the embodiments described hereinafter.

### BRIEF DESCRIPTION OF THE DRAWINGS

FIG. 1 shows a schematic set-up of a conventional optical disc drive that can be employed with the present invention;

FIG. 2 shows a schematic cross section through a master substrate before processing according to the present invention;

FIG. 3 shows a schematic cross section through a master substrate in a first processing step according to the present invention;

FIG. 4 shows a schematic cross section through a master substrate in a second processing step according to the present invention;

FIG. 5 shows pictures from an atomic force microscope (AFM pictures) illustrating a short pit;

FIG. 6 shows AFM pictures illustrating grooves;

FIG. 7 shows a section of an optical master substrate for illustrating the arrangement of a data pattern;

FIG. 8 shows a flow chart for illustrating an embodiment of a method according to the present invention.

### DESCRIPTION OF PREFERRED EMBODIMENTS

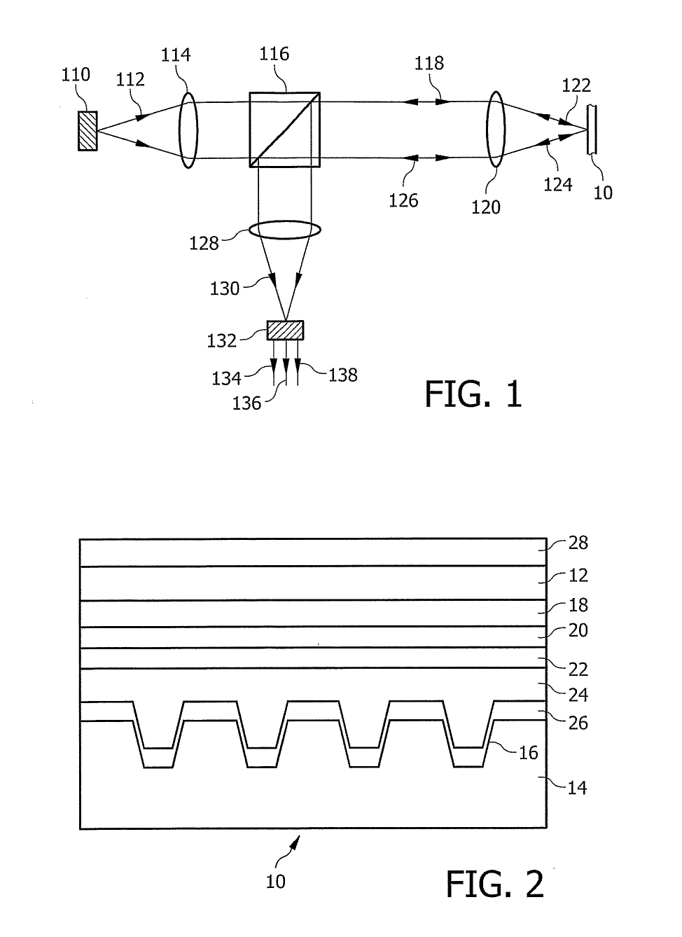

FIG. 1 shows a schematic set-up of a conventional optical disc drive that can be employed with the present invention. A radiation source 110, for example a semi-conductor laser, emits a diverging radiation beam 112. The beam 112 is made essentially parallel by a collimator lens 114, from which it is projected to a beam splitter 116. At least a part of the beam 118 is further projected to an objective lens 120, which focuses a converging beam 122 onto a master substrate 10. The master substrate 10 will be described in detail with reference to the figures below. The focused beam 122 is able to induce a phase change in the recording layer of the master substrate. On the other hand, the converging beam 122 is reflected into a diverging beam 124 and is then projected further as an essentially parallel beam 126 by the objective lens 120. At least part of the reflected beam 126 is projected to a condenser lens 128 by the beam splitter 116. This condenser lens 128 focuses a converging beam 130 onto a detector system 132. The detector system 132 is adapted to extract information from the light projected onto the detector system 132 and to transform this information into a plurality of electrical signals 134, 136, 138, for example an information signal 134, a focus error signal 136 and a tracking error signal 138. With reference to the present invention, the tracking error signal 138 is of particular relevance. The localization of the converging beam 122 on the master substrate 10 is controlled via a pre-groove structure in the master substrate 10. The grooves in the master substrate 10 generate an optical tracking error signal. The resulting interference pattern is finally projected onto the detector system 132, and it is symmetric in case the beam is perfectly centered with respect to the groove. A difference signal, the so-called push-pull signal, is created on the basis of multiple detectors or multiple detector segments of the detector system 132. It is zero in the case of perfect centering of the beam with respect to the groove. A deviation from the central position will lead to more or less light on the generally two detector parts. The difference signal becomes non-zero, and it can be used to re-align the spot with respect to the groove.

FIG. 2 shows a schematic cross section through a master substrate before processing according to the present invention. On top of the master substrate 10 a protection layer 28 is provided. The protection layer 28 is made of a material that well dissolves in conventional developer liquids, such as KOH and NaOH. For example the protection layer 28 comprises of ZnS—SiO₂ or photoresist. The thickness of the protection layer 28 is between 5 and 100 nm, preferably between 10 and 25 nm. Underneath the protection layer 28 the recording layer 12 is arranged. The recording materials are preferably so-called fast-growth phase-change materials, preferably of the composition: SnGeSb (Sn_{18.3}—Ge_{l2.6—Sb}_{69.2} (At %)) or Sb₂Te doped with In, Ge, etc, such as in InGeSbTe. These growth-dominated phase-change materials possess a high contrast in dissolution rate of the amorphous and crystalline phase. The amorphous marks, obtained by melt-quenching of the crystalline material, can be dissolved in conventional developer liquids, such as KOH and NaOH, but also HCl and HNO_{3.} Re-crystallisation in the tail of the mark can be used to reduce the marklength in a controlled way. Thereby it is possible to create marks with a length shorter than the optical spot size. In this way, the tangential data density can be increased. The data pattern thus written on the recording layer 12 can be transformed to a relief structure via etching. The thickness of the recording layer 12 is between 5 and 80 nm, preferably between 10 and 40 nm. Beneath the recording layer 12 a first interface layer 18 is provided. This interface layer 18 may be etchable as well. The patterned recording layer 12 then serves as a mask layer. The preferred material for the first interface layer 18 is ZnS—SiO₂. The thickness of the first interface layer 18 is between 5 and 80 nm, preferably between 10 and 40 nm. The first interface layer 18 is followed by a second interface layer 20 which is not etchable, and thus acts as a natural barrier. This second interface layer 20 is about 50 nm thick. Beneath the second interface layer 20 a semi-transparent metallic layer 22 is provided that serves as a heat-sink to remove the heat during recording, thereby enabling melt-quenching. Semi-transparent metals, such as Ag, or transparent heat-sink layers, such ITO or HfN, are proposed. The preferred thickness of the heat-sink layer 22 is between 5 and 40 nm. Below the heat-sink layer 22 and above the substrate 14 a leveling layer 24 is provided to level out the pre-grooves such that a planar recording stack remains. The leveling layer 24 is deposited via a spincoat process, or other type of process that enables filling and leveling of the grooves. The material for the leveling layer is preferably a non-absorbing, spincoatable organic material. The lowermost layer is the already mentioned substrate layer 14 that contains pre-grooves 16 for tracking purposes. In order to enhance the tracking error signal, a reflective layer 26 is deposited on the substrate layer.

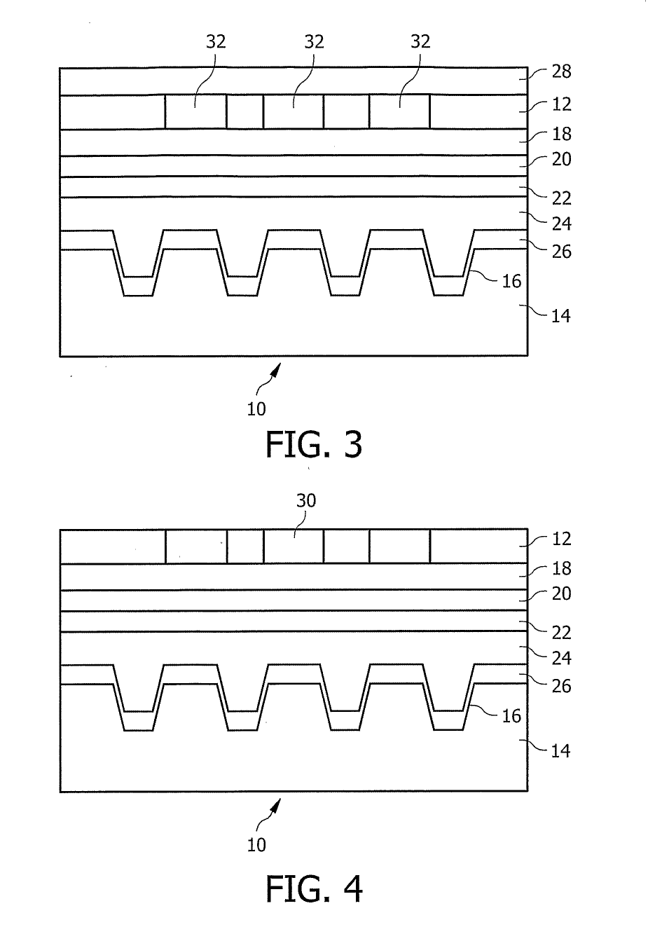

FIG. 3 shows a schematic cross section through a master substrate in a first processing step according to the present invention. In this processing step, recorded marks 32 have been generated in the recording layer 12. These recorded marks 32 are preferably amorphous areas written in a crystalline background. Instead of or additional to the protection layer 28 a cover layer may be provided to make the substrate compatible with the optical drive. For example, in the case of a Blue-ray disc a 100 μm cover is added to the disc. Marks are written in the recording layer via the conventional methods applied to rewritable optical discs. Write strategy optimization can be performed on the basis of a detection of the written marks. The feedback loop thus generated is very short, and the conventional disc drives provide this opportunity on the basis of minimum additional effort. After exposure, the 100 μm cover is dissolved in acetone or simply removed via pealing off. It is also possible to add a compensation glass substrate of 100 μm in between the master substrate and the objective lens. In that case, it is not necessary to add and remove the 100 μm cover layer after exposure of the record layer. The recorded marks 32 and the protection layer 28 are subsequently dissolved in conventional etch liquids, such as NaOH or KOH to end up with a high-density relief structure. This high-density relief structure 30 is shown in FIG. 4.

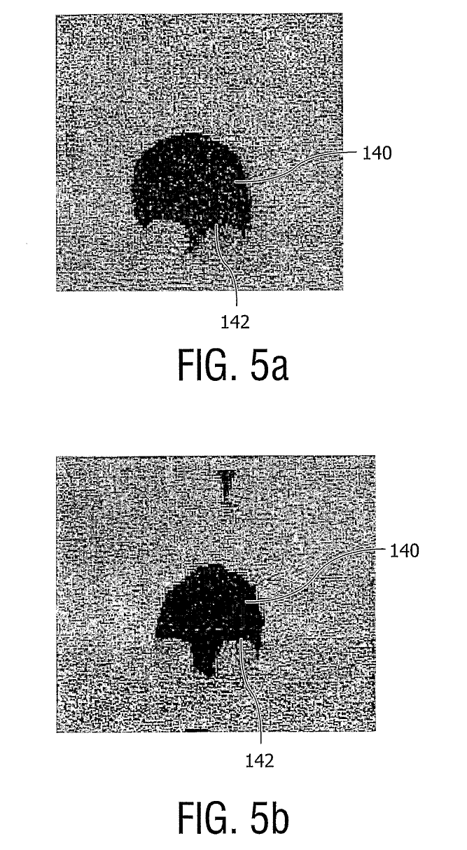

FIG. 5 shows pictures from an atomic force microscope (AFM pictures) illustrating a short pit 140. The pit 140 was generated with the proposed master substrate and according to the proposed method. The total dissolution time was 10 minutes in 10% NaOH solution. The pit shape resembles the typical crescent shape of the shortest marks. The pit width is almost twice the length of the pit. The pit length is reduced via the re-crystallization effect in the tail 142 of the pit. The crescent shape of the mark is perfectly transferred to the relief structure.

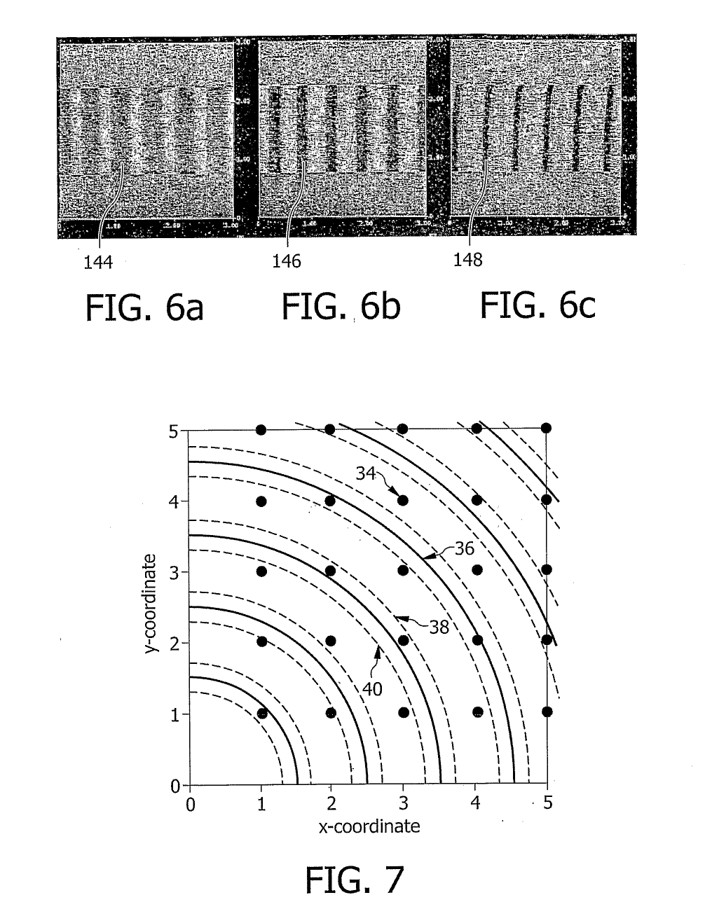

FIG. 6 shows AFM pictures illustrating grooves 144, 146, 148. A continuous laser power at a wavelength of 413 nm was supplied in each of the pictures a, b, and c, the laser power decreasing from a to c. The written amorphous trace was dissolved for 10 minutes in 10% NaOH solution. The groove depth was 20 nm.

FIG. 7 shows a section of an optical master substrate for illustrating the arrangement of a data pattern. The optimum push-pull tracking that is described above with reference to FIG. 1 will lead to an optical spot that perfectly follows the pre-groove. Optimum tracking is preferred in case a high-density master for mass-replication of optical discs is recorded. In that case, the relief structure should be a spiral of alternating lands and pits of different lengths, in which the data is encoded. If a two-dimensional high-density relief structure is required, such as a two-dimensional optical card, a stamp for micro-contact printing, or a raster, a more accurate positioning of the laser spot is required. One possibility to achieve this is selecting a pre-groove master substrate with a smaller track-pitch. However, a minimum track-pitch of about 250 nm is required to enable tracking in order to provide a sufficiently large push-pull signal. With an offset in the push-pull signal, the spot can be deliberately placed off-track. Thereby, for example, a rectangular data pattern 34, as shown in FIG. 5 may be achieved. The data points that form the rectangular data pattern 34 can be positioned to any location on the disc, particularly offset with respect to the central spiral 36 and the outer bounds 38, 40 of the focused laser spot. By this deliberately placing of the spot off-track, a high-positioning accuracy can be achieved on the basis of the push-pull signal.

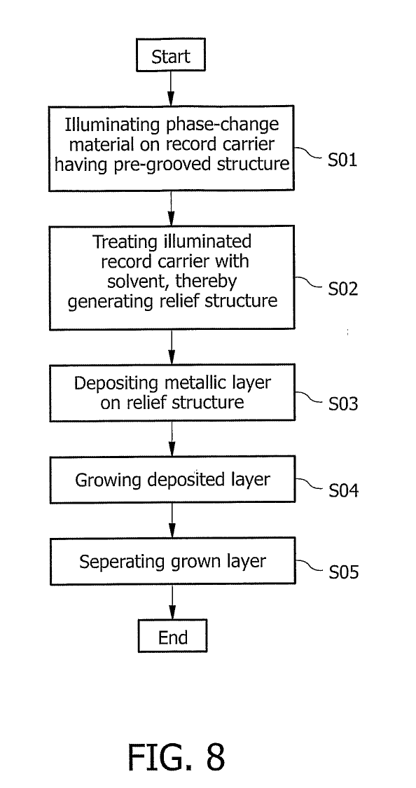

FIG. 8 shows a flow chart for illustrating an embodiment of a method according to the present invention. In a first step S01 the phase-change material on the master substrate having a pre-grooved structure is illuminated, preferably by a laser beam, thereby inducing a thermal transformation of the phase-change material, particularly a transition from a crystalline to an amorphous phase. Thereby the chemical properties with respect to a solvent are altered. Then, in step S02, the thus prepared master substrate is treated by a solvent, thereby generating a relief structure due to removing the amorphous regions. After this step, a depositing step S03 of a metallic layer on the relief structure is performed. In step S04, the depositing layer is grown to a desired thickness. Finally, in step S05 the grown layer is separated, thereby obtaining a stamper for the mask replication of optical discs.

Equivalents and modifications not described above may also be employed without departing from the scope of the invention, which is defined in the accompanying claims.

1. A master substrate (10) for optical recording comprising a recording layer (12) and a substrate layer (14),
the recording layer comprising a phase-change material, the properties with respect to chemical agents of which may be altered due to a phase change induced by projecting light on the recording layer, and
the substrate layer comprising a structure (16) for tracking purposes.

2. The master substrate according to claim 1, wherein a first interface layer (18) is arranged between the recording layer and the substrate layer.

3. The master substrate according to claim 2, wherein a second interface layer (20) is arranged between the first interface layer and the substrate layer, and the first interface layer (18) is etchable.

4. The master substrate according to claim 1, wherein a heat-sink layer (22) is arranged between the recording layer and the substrate layer.

5. The master substrate according to claim 1, wherein a leveling layer (24) is arranged between the recording layer and the substrate layer.

6. The master substrate according to claim 1, wherein a reflective layer (26) is arranged between the recording layer and the substrate layer.

7. The master substrate according to claim 1, wherein a protection layer (28) is arranged above the recording layer.

8. The master substrate according to claim 1, wherein the structure (16) for tracking purposes comprises of a pre-groove structure.

9. A method of manufacturing a stamper for replicating a high-density relief structure comprising the steps of:
illuminating a master substrate (10) in a conventional optical disc drive by a focused and modulated light beam, the master substrate comprising a recording layer (12) and a substrate layer (14), the recording layer comprising a phase-change material, the properties with respect to chemical agents of which may be altered due to a phase change induced by projecting light on the recording layer, and the substrate layer comprising a structure (16) for tracking purposes,
treating the previously illuminated master substrate with a solvent, thereby obtaining a relief structure (30),
depositing a metallic layer on the relief structure,
growing the deposited layer to a desired thickness, and
separating the grown layer.

10. The method according to claim 9, wherein the step of growing the deposited layer to a desired thickness comprises electro-chemical plating.

11. The method according to claim 9, wherein the structure for tracking purposes comprises of a pre-groove structure, and an interference pattern projected from the pre-groove structure onto a detector (132) is used for tracking.

12. The method according to claim 9, wherein the structure for tracking purposes comprises of pre-grooves, and the light beam is deliberately placed off-track, so as to write a data pattern that is not restricted to following the pre-groove structure.

13. A method of producing an optical data carrier using a master substrate according claim 1.
